(19) United States
(12) Patent Application Publication
(10) Pub. No.: US 2023/0074032 A1
(43) Pub. Date: Mar. 9, 2023

(54) SOLAR CELL AND METHOD FOR MANUFACTURING SOLAR CELL

(71) Applicant: KANEKA CORPORATION, Osaka (JP)

(72) Inventors: Katsunori KONISHI, Settsu-shi (JP); Kunta YOSHIKAWA, Settsu-shi (JP)

(73) Assignee: KANEKA CORPORATION, Osaka (JP)

(21) Appl. No.: 18/054,405

(22) Filed: Nov. 10, 2022

Related U.S. Application Data
(63) Continuation of application No. PCT/JP2021/017823, filed on May 11, 2021.

(30) Foreign Application Priority Data
May 13, 2020 (JP) 2020-084411

(51) Int. Cl. H01L 31/18; H01L 31/0224

(52) U.S. Cl. CPC H01L 31/1816; H01L 31/1888; H01L 31/1896; H01L 31/022441

(57) ABSTRACT

A solar cell includes a semiconductor substrate; a plurality of band-like first semiconductor layers and a plurality of second semiconductor layers provided alternatively on a back surface side of the semiconductor substrate; a band-like first electrode stacked on the first semiconductor layer and a band-like second electrode stacked on the second semiconductor layer; and a band-shaped or linear insulating body stacked on a back surface of the first semiconductor layer in a region distanced from the first electrode and an edge on a side of the second semiconductor layer.

### CROSS-REFERENCE TO RELATED APPLICATIONS

This application claims benefit of priority to International Patent Application No. PCT/JP2021/017823, filed May 11, 2021, and to Japanese Patent Application No. 2020-084411, filed May 13, 2020, the entire contents of each are incorporated herein by reference.

### BACKGROUND

### Technical Field

The present disclosure relates to a solar cell and a method for manufacturing solar cells.

### Background Art

A back contact-type solar cell has been known in which band-like p-type semiconductor layers and n-type semiconductor layers are alternately formed via an intrinsic semiconductor layer on the back surface side of a semiconductor substrate, and electrodes are stacked on each of the p-type semiconductor layers and n-type semiconductor layers. In such a back contact-type solar cell, in order to prevent leakage between the electrode on the p-type semiconductor layer and the electrode on the n-type semiconductor layer, a configuration has been known which arranges an insulating material in a band shape on the back surface side of one semiconductor layer.

As an example, Japanese Unexamined Patent Application, Publication No. 2018-164057 discloses a production method of a solar battery including steps of forming an intrinsic first amorphous-based semiconductor film all over a back surface of a semiconductor substrate of a conductivity type having a light-receiving face and a rear face; forming a second amorphous-based semiconductor film containing impurities indicative of a conductivity type all over the first amorphous-based semiconductor film; and forming on the second amorphous-based semiconductor film, a first etching mask layer having an electrical insulating property so that the first and second amorphous-based semiconductor films remain in a comb-shaped form, followed by etching the first and second amorphous-based semiconductor films. The production method in Japanese Unexamined Patent Application, Publication No. 2018-164057 further includes forming an intrinsic third amorphous-based semiconductor film on a back surface of the semiconductor substrate exposed by etching and on the first etching mask layer; and forming a fourth amorphous-based semiconductor film containing impurities indicative of a conductivity type different from the conductivity type of the second amorphous-based semiconductor layer all over the third amorphous-based semiconductor film; forming a second etching mask layer so that partial overlap with the first etching mask layer, the third amorphous-based semiconductor film and the fourth amorphous-based semiconductor film in a short side direction from an end of the first etching mask layer remain in a comb shape, followed by etching the first etching mask layer and the third and fourth amorphous-based semiconductor films. In addition, the production method in Japanese Unexamined Patent Application, Publication No. 2018-164057 includes forming a first electrode on the second amorphous-based semiconductor layer in a region without the first etching mask layer; and forming a second electrode on the fourth amorphous-based semiconductor layer in a region without the overlap.

The production method disclosed in Japanese Unexamined Patent Application, Publication No. 2018-164057 omits a step of forming an insulation layer to reduce the production cost of a solar cell, by using part of the first etching mask layer as an insulation layer preventing leakage between electrodes.

### SUMMARY

However, as a result of considering the production method of a solar cell disclosed in Japanese Unexamined Patent Application, Publication No. 2018-164057, it was ascertained that damage occurs to the boundary region between the first semiconductor layer (first amorphous semiconductor film) and second semiconductor layer (second amorphous semiconductor film) in the process, whereby the solar cell characteristics decline. The present disclosure thus provides a solar cell and a solar cell manufacturing method which can prevent leakage between electrodes, while suppressing a decline in solar cell characteristics at the boundary region between a first semiconductor layer and a second semiconductor layer.

A solar cell according to an aspect of the present disclosure includes a semiconductor substrate; a plurality of band-like first semiconductor layers and a plurality of second semiconductor layers provided alternatively on a back surface side of the semiconductor substrate; a band-like first electrode stacked on the first semiconductor layer and a band-like second electrode stacked on the second semiconductor layer; and a band-shaped or linear insulating body stacked on a back surface of the first semiconductor layer in a region distanced from the first electrode and an edge on a side of the second semiconductor layer.

In the solar cell as described in the aspect of the present disclosure, the second semiconductor layer may be stacked on the back surface side of the insulating body.

The solar cell as described in the aspect of the present disclosure may further include an intrinsic semiconductor layer interposed between the insulating body and the second semiconductor layer.

In the solar cell as described in the aspect of the present disclosure, the intrinsic semiconductor layer may be stacked so as to extend to a back surface side of the insulating body from between the semiconductor substrate and the first semiconductor layer and the second semiconductor layer through between the first semiconductor layer and the second semiconductor layer and through the back surface side of the first semiconductor, and the second semiconductor layer may be stacked so as to cover substantially an entire surface of a region of the intrinsic semiconductor layer stacked on a back surface side of the first semiconductor layer.

In the solar cell as described in the aspect of the present disclosure, the second electrode may be stacked so as to cover at least a portion of a region of the second semiconductor layer stacked on a back surface side of the first semiconductor layer.

In the solar cell as described in the aspect of the present disclosure, the second semiconductor layer may be stacked continuously until a back surface side of the first semiconductor layer, and the second electrode may include a planar shape substantially equal to the second semiconductor layer.

A solar cell manufacturing method according to another aspect of the present disclosure includes the steps of stacking a first semiconductor layer on a back surface side of a semiconductor substrate; stacking a lift-off layer on a back surface side of the first semiconductor layer; removing the first semiconductor layer and the lift-off layer in a stripe shape by etching which forms a stripe-like etching mask on a back surface side of the lift-off layer; stacking a second semiconductor layer on a back surface of a layered body of a semiconductor substrate, the first semiconductor layer and the lift-off layer; removing a central part of the lift-off layer and the second semiconductor layer stacked thereon, in a condition such that leaves a width-direction end of the lift-off layer in a band shape or line shape; and stacking a first electrode on a back surface of the first semiconductor layer and stacking a second electrode on a back surface of the second semiconductor layer.

According to the present disclosure, it is possible to provide a solar cell and a solar cell manufacturing method which can prevent leakage between electrodes.

### BRIEF DESCRIPTION OF THE DRAWINGS

FIG. 1 is a cross-sectional view showing the configuration of a solar cell according to a first embodiment of the present disclosure;

FIG. 2 is a flowchart showing a sequence of a manufacturing method of the solar cell in FIG. 1;

FIG. 3 is a cross-sectional view showing a process in the solar cell manufacturing method in FIG. 2;

FIG. 4 is a cross-sectional view showing a process after FIG. 3 in the solar cell manufacturing method in FIG. 2;

FIG. 5 is a cross-sectional view showing a process after FIG. 4 in the solar cell manufacturing method in FIG. 2;

FIG. 6 is a cross-sectional view showing a process after FIG. 5 in the solar cell manufacturing method in FIG. 2;

FIG. 7 is a cross-sectional view showing the configuration of a solar cell according to a second embodiment of the present disclosure;

FIG. 8 is a cross-sectional view showing the configuration of a solar cell according to a third embodiment of the present disclosure;

FIG. 9 is a cross-sectional view showing the configuration of a solar cell according to a fourth embodiment of the present disclosure; and

FIG. 10 is a cross-sectional view showing the configuration of a solar cell according to a fifth embodiment of the present disclosure.

### DETAILED DESCRIPTION

Hereinafter, each embodiment of the present disclosure will be explained while referencing the drawings. It should be noted that, although hatching, member reference numbers, etc. may be omitted for convenience, in such a case, other drawings shall be referenced. In addition, the dimensions of various members in the drawings are adjusted to facilitate understanding for convenience. Furthermore, in the following explanation, for embodiments explained later, the same reference numbers are attached to constituent elements which are identical to a previously explained embodiment, and redundant explanations will be omitted.

<First Embodiment>

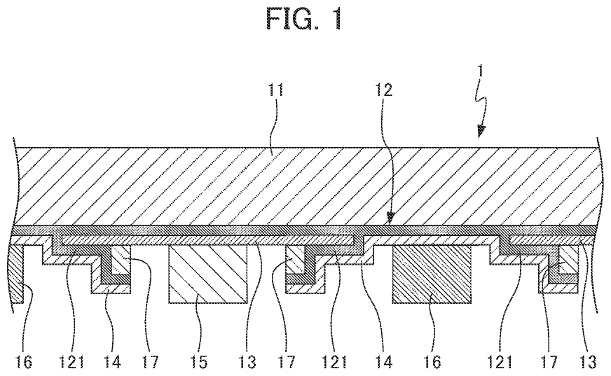

FIG. 1 is a cross-sectional view showing the configuration of a solar cell 1 according to a first embodiment of the present disclosure. The solar cell 1 includes a semiconductor substrate 11; intrinsic semiconductor layer 12 stacked on the back surface of the semiconductor substrate 11; a plurality of first semiconductor layers 13 and a plurality of second semiconductor layers 14 provided alternately on the back surface side of the semiconductor substrate via the intrinsic semiconductor layer 12; a band-like first electrode 15 stacked on the back surface side of the first semiconductor layer 13 and a band-like second electrode 16 stacked on the second semiconductor layer 14; and a band-shaped or linear insulating body 17 stacked on a back surface of the first semiconductor layer 13 in a region distanced from the first electrode and the edge on a side of the second semiconductor layer.

The semiconductor substrate 11 can be formed from a crystalline silicon material such as a single crystal silicon or polycrystal silicon. In addition, it may be formed from other semiconductor materials such as gallium arsenide (GaAs). The semiconductor substrate 11 is an n-type semiconductor substrate in which n-type dopant is doped to the crystalline silicon material, for example. As the n-type dopant, for example, phosphorus (P) can be exemplified. The semiconductor substrate 11 functions as the photoelectric conversion substrate which generates optical carriers (electrons and electron holes) by absorbing incident light from a light receiving surface side. By the crystalline silicon being used as the material of the semiconductor substrate 11, even in a case of the dark current being relatively small, and the intensity of incident light being low, a relatively high output (stable output irrespective of illuminance) is thereby obtained.

An intrinsic semiconductor layer 12 suppresses recombination of carrier by forming a depletion layer. The intrinsic semiconductor layer 12 can form from so-called i-type amorphous silicon, for which the content of impurities is sufficiently small.

The intrinsic semiconductor layer 12 is stacked so as to extend from between the semiconductor substrate 11 and the first semiconductor layer 13 and second semiconductor layer 13, through between the first semiconductor layer 13 and second semiconductor layer 14 and through the back surface side of the first semiconductor layer 13, to the back surface side of the insulating body 17. In other words, the intrinsic semiconductor layer 12 has an extension part 121 which branches off between the first semiconductor layer 13 and second semiconductor layer 14 and extends to the back side surface of the first semiconductor layer 13, and stacked on the back surface of a region of the first semiconductor layer 13 projecting more to the side of the second semiconductor layer 14 than the insulating body 17, and on the back surface of the insulating body 17.

The extension part 121 of the intrinsic semiconductor layer 12 insulates between the first semiconductor layer 13 and second semiconductor layer 14, and improves the characteristic of the end of the first semiconductor layer 13. In more detail, in the manufacturing process of the solar cell 1 described later, it is possible to recover, during formation of the extension part 121, the damage received by the surface of the end of the first semiconductor layer 13 by being exposed to etching solution by side etching upon etching to demarcate the edges of the first semiconductor layer 13. It should be noted that, although damage can be received from side etching also at the surface of the first semiconductor layer 13 of a portion at which the insulating body 17 is stacked upon etching, damage of this portion can remain even if forming the extension part 121. However, since the first semiconductor layer 13 has portions without damage at both sides of the portion where the insulating body 17 is stacked, it is possible to disperse and collect at portions without damage at both sides the carrier to be collected at a portion with damage. For this reason, by the extension part 121 being stacked on the back surface of the end of the first semiconductor layer 13, a performance decline caused by damage of etching at the entirety of the first semiconductor layer 13 is suppressed.

The first semiconductor layer 13 and second semiconductor layer 14 are formed in a band shape extending in the same direction as each other. The second semiconductor layer 14 is stacked so as to cover a region of the intrinsic semiconductor layer 12 stacked on the back surface side of the first semiconductor layer 13, i.e. substantially the entire surface of the extension part 121. Therefore, the second semiconductor layer 14 is also stacked on the back surface side of the insulating body 17, and the intrinsic semiconductor layer 12 is interposed between the insulating body 17 and second semiconductor layer. It should be noted that a plurality of the first semiconductor layers 13 and a plurality of the second semiconductor layers 14 may ends connected to form a comb shape with each other. In addition, in FIG. 1, a stacked portion assumes a step shape due to the thickness of each constituent element being greatly exaggerated; however, the thickness of each constituent element is actually very small, and each constituent element can be formed planarly.

The first semiconductor layer 13 and second semiconductor layer 14 have different conductivity types from each other. The first semiconductor layer 13 and second semiconductor layer 14 form an electric field attracting the carriers generated in the semiconductor substrate 11, by abundantly generating different carriers from each other.

More specifically, the first semiconductor layer 13 can be formed from p-type semiconductor, and the second semiconductor layer 14 can be formed from n-type semiconductor. The first semiconductor layer 13 and second semiconductor layer 14 can be formed from an amorphous silicon material containing dopant which imparts the desired conductivity type, for example. As the p-type dopant, for example, boron (B) can be exemplified, and as the n-type dopant, for example, the aforementioned phosphorus (P) can be exemplified.

The first electrode 15 and second electrode 16 are provided for extracting charge from the first semiconductor layer 13 and second semiconductor layer 14. The first electrode 15 and second electrode 16 also may be molded in a comb shape similarly to the first semiconductor layer 13 and second semiconductor layer 14. The first electrode 15 and second electrode 16 can be formed from an electrically conductive paste containing electrically conductive particles and binder. As a specific electrically conductive paste, typically, it is possible to exemplify silver paste. By using an electrically conductive paste, it is possible to relatively cheaply form the first electrode 15 and second electrode 16 having sufficient thickness such that can reduce the electrical resistance.

The insulating body 17, in the case of forming a solar cell module by sealing the solar cells 1 with a sealant with ethylene-vinyl acetate copolymer (EVA), for example, as a main component, prevents leakage occurring by charge migrating along the boundary between the sealant and the first semiconductor layer 13 and second semiconductor layer 14. More specifically, if moisture infiltrates the sealant, the moisture infiltrating to the boundary between the sealant and the first semiconductor layer 13 and second semiconductor layer 14, which are heterogenous materials (inorganic material and organic material) tends to accumulate, and charge can migrate through this layer of moisture. However, the adhesion raises between the insulating body 17 and sealant, which are homogeneous materials (both organic materials), and moisture hardly accumulates at the boundary; therefore, it is possible to make an obstacle preventing migration of charge.

As the lower limit for the interval between the insulating body 17 and the edge of the first semiconductor layer 13, i.e. extension length from insulating body 17 of the first semiconductor layer 13, 10 μm is preferable, and 20 μm is more preferable for damage recovery. On the other hand, as the upper limit for the interval between the insulating body 17 and the edge of the first semiconductor 13, 300 μm is preferable, and 200 μm is more preferable for facilitating arrangement of the insulating body 17.

As the lower limit for the width of the insulating body 17, 5 μm is preferable, and 8 μm is more preferable, for obtaining a favorable leakage prevention effect. On the other hand, as the upper limit for the width of the insulating body 17, 100 μm is preferable, and 50 μm is more preferable, for optimizing the widths of the first semiconductor layer 13, second semiconductor layer 14, first electrode 15 and second electrode 16.

As the lower limit for the interval between the insulating body 17 and first electrode 15, 50 μm is preferable, and 100 μm is more preferable, for preventing short circuit between the first electrode 15 and second semiconductor layer 14. On the other hand, as the upper limit for the interval between the insulating body 17 and first electrode 15, 300 μm is preferable, and 200 μm is more preferable, for optimizing the widths of the first semiconductor layer 13, second semiconductor layer 14, first electrode 15 and second electrode 16.

<Solar Cell Manufacturing Method>

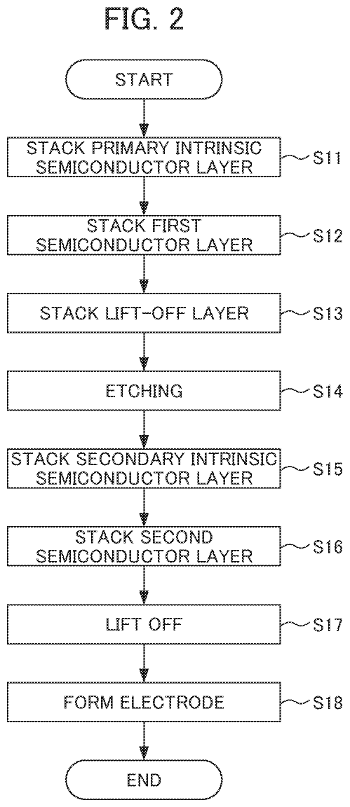

The solar cell manufacturing method of FIG. 2 is one embodiment of a solar cell manufacturing method according to the present disclosure.

The solar cell manufacturing method according to the present embodiment includes a primary intrinsic semiconductor layer stacking step (Step S11); first semiconductor layer stacking step (Step S12); lift-off layer stacking step (Step S13); etching step (Step S14); secondary intrinsic semiconductor layer stacking step (Step S15); second semiconductor layer stacking step (Step S16); lift-off step (Step S17); and electrode stacking step (Step S18).

In the primary intrinsic semiconductor layer stacking step of Step S11, the intrinsic semiconductor layer 12 is stacked on the entire back surface of the semiconductor substrate 11. The intrinsic semiconductor layer 12 can be stacked by plasma CVD, for example.

In the first semiconductor layer stacking step of Step S12, the first semiconductor layer 13 is stacked on the back surface side of the semiconductor substrate 11 on which the intrinsic semiconductor layer 12 is stacked, i.e. entire surface on the back surface side of the intrinsic semiconductor layer 12. The first semiconductor layer 13 can be stacked by plasma CVD, for example, similarly to the intrinsic semiconductor layer 12.

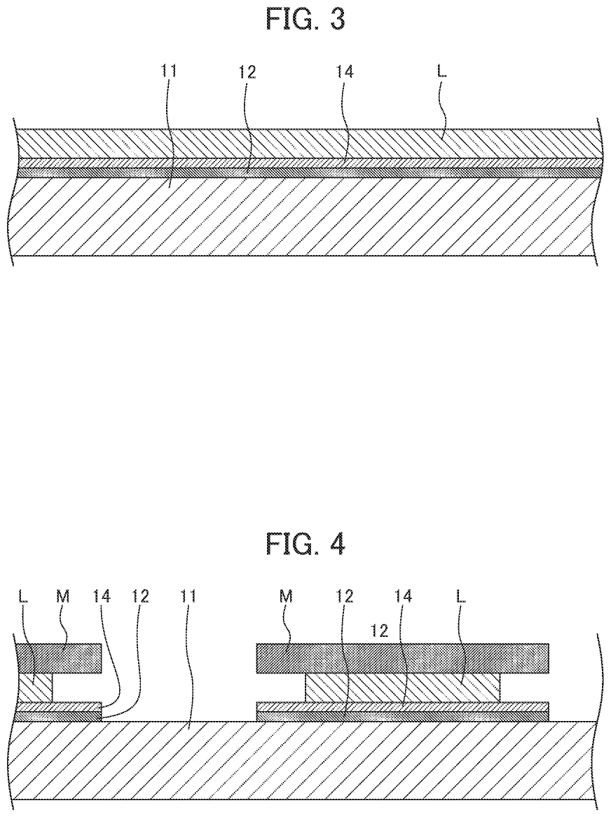

In the lift-off layer stacking step of Step S13 the lift-off layer L is staked on the entire surface on the back surface side of the layer of the first semiconductor layer 13, as shown in FIG. 3. The lift-off layer L constitutes the insulating body 17, by partially remaining. The lift-off layer L can be formed by a material such as silicon oxide (SiO), silicon nitride (SiN) or silicon oxynitride (SiON), or a material containing a plurality of these, for example. The lift-off layer L can be stacked by CVD, for example.

In the etching step of Step S14, by etching that forms a stripe-like etching mask M on the back surface side of the lift-off layer L, the intrinsic semiconductor layer 12, first semiconductor layer 13 and lift-off layer L are removed in a stripe shape. In more detail, the etching step includes a step of forming an etching mask; a step of removing the intrinsic semiconductor layer 12, first semiconductor layer 13 and lift-off layer L using an etching solution; and a step of removing the etching mask using a mask stripping solution.

The etching mask M is formed in a planar shape matching the desired shape of the first semiconductor layer 13, for example, using printing technology, photolithographic technology, etc. As the etching solution, for example, it is possible to use a mixed solution of hydrofluoric acid (HF) and nitric acid (HNO₃). As the mask stripping solution, for example, it is possible to use an organic solvent such as acetone.

By increasing the solubility of the lift-off layer L to the etching solution compared to the intrinsic semiconductor layer 12 and first semiconductor layer 13, only the edge of the lift-off layer L is drawn back from the edge of the etching mask M by side etching, as shown in FIG. 4. The insulating body 17 can thereby be made to distance from the edge of the first semiconductor layer 13. At this time, the first semiconductor layer 13 of the portion from which the lift-off layer L retreated, and the first semiconductor layer 13 directly below the end of the remaining lift-off layer L which has not been completely removed, but remains with the etching solution soaked therein are exposed to the etching solution, albeit for a relatively short time. For this reason, the surface of the end of the first semiconductor layer 13 receives damage from the etching solution.

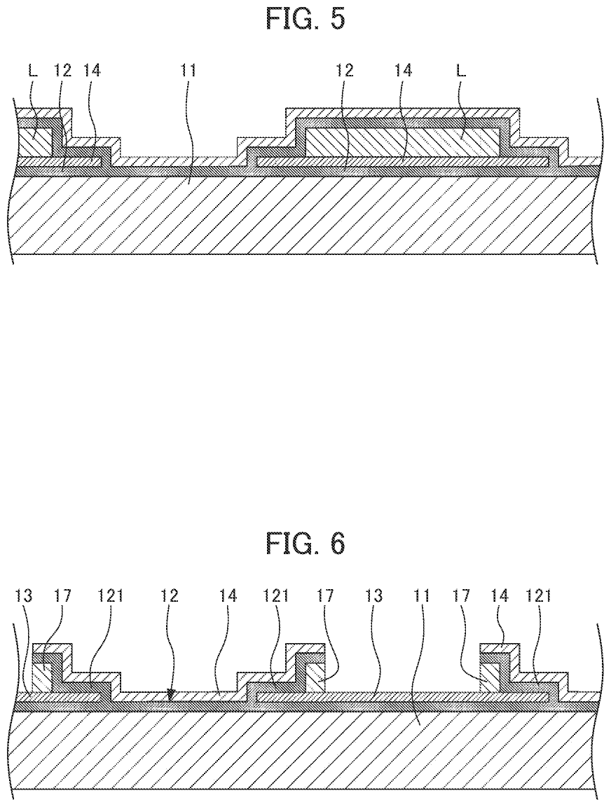

In the secondary intrinsic semiconductor layer stacking step of Step S15, the intrinsic semiconductor layer 12 on the entire back surface of the layered body of the semiconductor substrate 11, intrinsic semiconductor layer 12, first semiconductor layer 13 and lift-off layer L, as shown in FIG. 5. Lamination of the intrinsic semiconductor layer 12 in the secondary intrinsic semiconductor layer stacking step also can laminate by plasma CVD, for example, similarly to the primary intrinsic semiconductor layer stacking step.

This secondary intrinsic semiconductor layer stacking step laminates a similar material as the first semiconductor layer 13, except for not containing trace dopant by a similar process as the first semiconductor layer stacking step. For this reason, by filling in a scratch formed in the surface of the first semiconductor layer 13 in the etching step with the same kind of material, it is possible to restore damage from etching of an end region of the first semiconductor layer 13 in which there is no lift-off layer L. Although damage may remain in the first semiconductor layer 13 immediately below the end of the lift-off layer L, so long as the area of the region having damage is the same, the performance decline of the first semiconductor layer 13 becomes smaller when having damage at the inside than when having damage at the end of the first semiconductor layer 13.

In the second semiconductor layer stacking step of Step S16, the second semiconductor layer 14 is stacked on the entire back surface of the layered body of the semiconductor substrate 11, intrinsic semiconductor layer 12, first semiconductor layer 13 and lift-off layer L, i.e. back surface of the intrinsic semiconductor layer 12 stacked in the secondary intrinsic semiconductor layer stacking step. The second semiconductor layer 14 can be stacked by plasma CVD, for example.

In the lift-off step of Step S17, the central part of the lift-off layer M and the intrinsic semiconductor layer 12 and second semiconductor layer 14 stacked thereon are removed, under conditions such that leave the width-direction end of the lift-off layer L in a band shape or line shape, as shown in FIG. 6. As an example, by forming a region in which a solution dissolving the lift-off layer tends to penetrate by providing a cut or opening, for example, in the intrinsic semiconductor layer 12 and second semiconductor layer 14 stacked in the width-direction central part of the lift-off layer L, it is possible to remove the lift-off layer M in order from the width-direction central part. If adjusting the immersion time in the solution, it is possible to form the insulating body 17 by leaving the width-direction end of the lift-off layer L. As the solution dissolving the lift-off layer L, it is possible to use an acid solution such as hydrofluoric acid, for example.

In the electrode stacking step of Step S18, each the first electrode 15 is stacked on the back surface of the first semiconductor layer 13, and the second electrode 16 on the back surface of the second semiconductor layer 14. The first electrode 15 and second electrode 16 can be formed by the printing and firing of an electrically-conductive paste. As the printing method of the electrically-conductive paste, it is possible to employ screen printing, for example.

In the above way, in the solar cell manufacturing method according to the present embodiment, by forming the insulating body 17 by leaving the end of the lift-off layer M, it is possible to relatively cheaply manufacture the solar cell 1 which can prevent leakage between the first electrode 15 and second electrode 16.

<Second Embodiment>

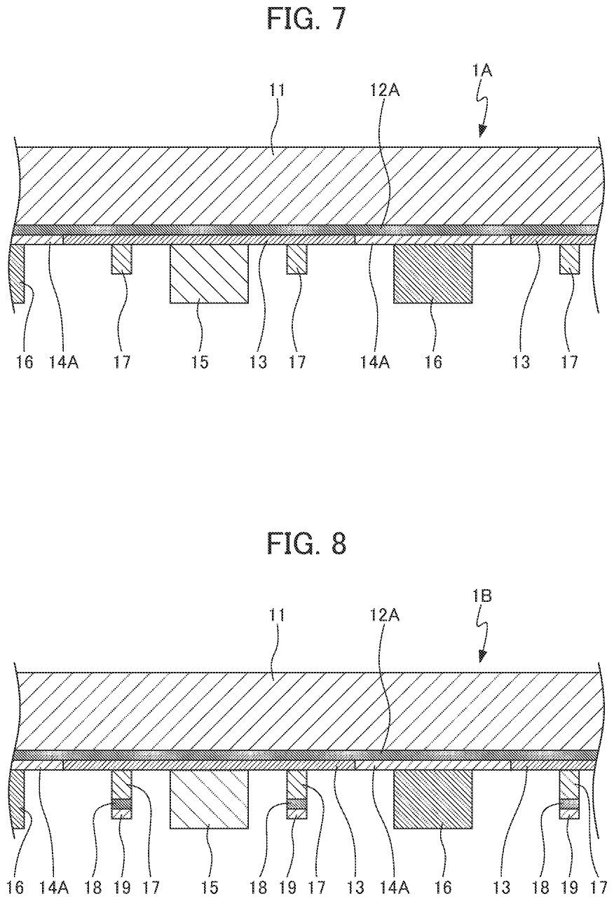

FIG. 7 is a cross-sectional view showing the configuration of a solar cell 1A according to a second embodiment of the present disclosure. The solar cell 1A includes the semiconductor substrate 11; intrinsic semiconductor layer 12A stacked on the back surface of the semiconductor substrate 11; a plurality of first semiconductor layers 13 and plurality of second semiconductor layers 14A provided alternately on the back surface side of the semiconductor substrate via the intrinsic semiconductor layer 12A; a band-like first electrode 15 stacked on the back surface side of the first semiconductor layer 13 and a band-like second electrode 16 stacked on the second semiconductor layer 14A; and the band-shaped or linear insulating body 17 stacked on the back surface of the first semiconductor layer 13 in regions distanced from the first electrode 15 and an edge on the second semiconductor layer 14A side.

In the solar cell 1A of FIG. 7, the intrinsic semiconductor layer 12A and second semiconductor layer 14A do not extend to the back surface side of the first semiconductor layer 13. In other words, the intrinsic semiconductor layer 12A is a single layer stacked on the back surface of the semiconductor substrate 11, and the second semiconductor layer 14A is stacked only on an un-stacked region of the first semiconductor layer 13. For this reason, the insulating body 17 is not covered by other constituent elements on the back surface side.

The solar cell 1A of FIG. 7 can be manufactured by patterning by forming a dedicated resist pattern on each of the first semiconductor layer 13, second semiconductor layer 14A and insulating body 17.

Since the second semiconductor layer 14A in particular is distanced from the insulating body 17, the solar cell 1A of FIG. 7 can suppress the occurrence of leakage current between the first electrode 15 and second semiconductor layer 14A.

<Third Embodiment>

FIG. 8 is a cross-sectional view showing the configuration of a solar cell 1B according to a third embodiment of the present disclosure. The solar cell 1B includes the semiconductor substrate 11; the intrinsic semiconductor layer 12A stacked on the back surface of the semiconductor substrate 11; a plurality of the first semiconductor layers 13 and a plurality of the second semiconductor layers 14A provided alternately on the back surface side of the semiconductor substrate via the intrinsic semiconductor layer 12A; the band-like first electrode 15 stacked on the back surface side of the first semiconductor layer 13 and the band-like second electrode 16 stacked on the second semiconductor layer 14A; the band-shaped or line-shaped insulating body 17 stacked on the back surface of the first semiconductor layer 13 in a region distanced from the first electrode 15 and edge on the side of the second semiconductor layer 14A; an intrinsic semiconductor cap part 18 stacked on the back surface of the insulating body 17; and a second semiconductor cap part 19 stacked on the back surface of the intrinsic semiconductor cap part 18.

The solar cell 1B of FIG. 8, as an example, can be manufactured by forming the first semiconductor layer 13 and second semiconductor layer 14A, followed by forming the lift-off layer opening a region forming the insulating body 17, and sequentially stacking the material forming the insulating body 17, material forming the intrinsic semiconductor cap part 18, and material forming the second semiconductor cap part 19, and dissolving the lift-off layer to remove together with the material stacked on the back surface side thereof.

<Fourth Embodiment>

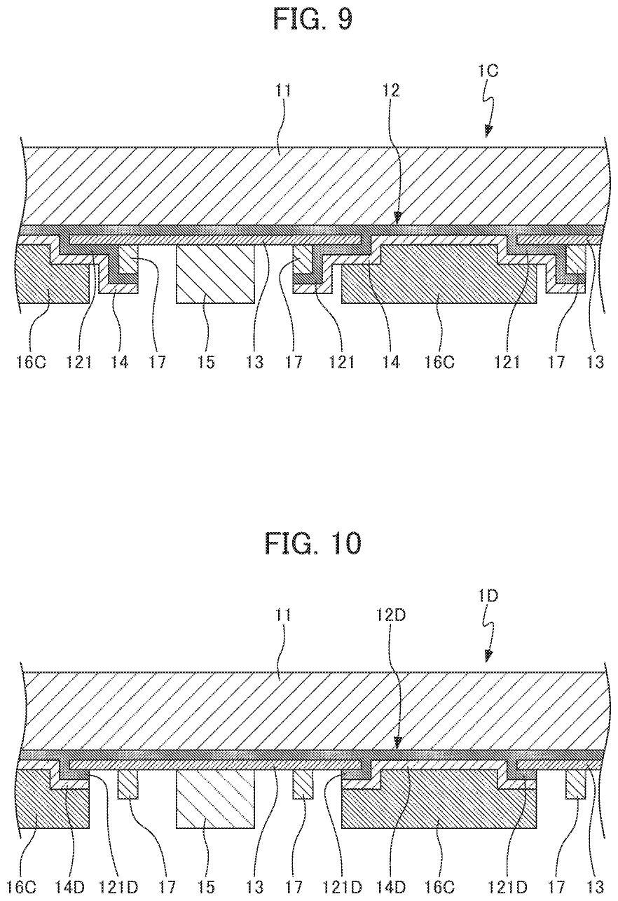

FIG. 9 is a cross-sectional view showing the configuration of a solar cell 1C according to a fourth embodiment of the present disclosure. The solar cell 1C includes the semiconductor substrate 11; the intrinsic semiconductor layer 12 stacked on the back surface of the semiconductor substrate 11; a plurality of first semiconductor layers 13 and plurality of second semiconductor layers 14 provided alternately on the back surface side of the semiconductor substrate via the intrinsic semiconductor layer 12; a band-like first electrode 15 stacked on the back surface side of the first semiconductor layer 13 and a band-like second electrode 16C stacked on the second semiconductor layer 14; and the band-shaped or line-shaped insulating body 17 stacked on a back surface of the first semiconductor layer 13 in a region distanced from the first electrode 15 and the edge on the side of the second semiconductor layer 14.

In the solar cell 1C of FIG. 9, the second electrode 16C is stacked so as to cover at least a portion of the region stacked on the back surface side of the first semiconductor layer 13 of the second semiconductor layer 14. In this way, by enlarging the width of the second electrode 16C, it is possible to improve the efficiency of current collection from the second semiconductor layer 14.

<Fifth Embodiment>

FIG. 10 is a cross-sectional view showing the configuration of a solar cell 1D according to a fifth embodiment of the present disclosure. The solar cell 1D includes the semiconductor substrate 11; an intrinsic semiconductor layer 12D stacked on the back surface of the semiconductor substrate 11; a plurality of the first semiconductors 13 and a plurality of the second semiconductor layers 14D provided alternately on the back surface side of the semiconductor substrate via an intrinsic semiconductor layer 12D; a band-like first electrode 15 stacked on the back surface side of the first semiconductor layer 13 and a band-like second electrode 16C stacked on the second semiconductor layer 14D; and a band-shaped or line-shaped insulating body 17 stacked on the back surface of the first semiconductor layer 13 in a region distanced from the first electrode 15 and edge on a side of the second semiconductor layer 14D.

In the solar cell 1D of FIG. 10, the intrinsic semiconductor layer 12D has an extension part 121D which branches between the first semiconductor layer 13 and second semiconductor layer 14D and extends to the back surface side of the first semiconductor layer 13, and ends at a position distanced from the insulating body 17. The second semiconductor layer 14D ends at the same position as the extension part 121D of the intrinsic semiconductor layer 12D. In other words, the second semiconductor layer 14D is stacked continuously until the back surface side of the first semiconductor layer 13 via the intrinsic semiconductor layer 12D.

The solar cell 1D of FIG. 10 can be manufactured by removing portions of the intrinsic semiconductor layer 12 and the second semiconductor layer 14 exposed from the second electrode 16C, by etching the solar cell 1C of FIG. 9 with the second electrode 16C as a mask. Therefore, in the solar cell 1D of the present embodiment, the second electrode 16C has a planar shape substantially matching the intrinsic semiconductor layer 12D and second semiconductor layer 14D.

By removing the portion exposed from the intrinsic semiconductor layer 12 and second electrode 16C of the second semiconductor layer 14 in this way, it is possible to more reliably suppress leakage current between the first electrode 15 and second semiconductor layer 14D.

Although embodiments of the present disclosure have been explained above, the present disclosure is not limited to the aforementioned embodiments, and various changes and modifications thereto are possible. As an example, the solar cell according to the present disclosure may not necessarily include the intrinsic semiconductor layer, and may include further constituent elements such as a passivation layer, anti-reflection film and protective film, in addition to the aforementioned constituent elements.

What is claimed is:

1. A solar cell comprising:
a semiconductor substrate;
a plurality of band-like first semiconductor layers and a plurality of second semiconductor layers configured alternatively on a back surface side of the semiconductor substrate;
a band-like first electrode stacked on the first semiconductor layer and a band-like second electrode stacked on the second semiconductor layer; and
a band-shaped or linear insulating body stacked on a back surface of the first semiconductor layer in a region distanced from the first electrode and an edge on a side of the second semiconductor layer.

2. The solar cell according to claim 1, wherein
the second semiconductor layer is stacked on a back surface side of the insulating body.

3. The solar cell according to claim 2, further comprising:
an intrinsic semiconductor layer interposed between the insulating body and the second semiconductor layer.

4. The solar cell according to claim 3, wherein
the intrinsic semiconductor layer is stacked to extend to a back surface side of the insulating body from between the semiconductor substrate and the first semiconductor layer and the second semiconductor layer through between the first semiconductor layer and the second semiconductor layer and through the back surface side of the first semiconductor, and
the second semiconductor layer is stacked to cover substantially an entire surface of a region of the intrinsic semiconductor layer stacked on a back surface side of the first semiconductor layer.

5. The solar cell according to claim 4, wherein
the second electrode is stacked to cover at least a portion of a region of the second semiconductor layer stacked on a back surface side of the first semiconductor layer.

6. The solar cell according to claim 1, wherein
the second semiconductor layer is stacked continuously to a back surface side of the first semiconductor layer, and
the second electrode includes a planar shape substantially equal to the second semiconductor layer.

7. A method of manufacturing a solar cell comprising:
stacking a first semiconductor layer on a back surface side of a semiconductor substrate;
stacking a lift-off layer on a back surface side of the first semiconductor layer;
removing the first semiconductor layer and the lift-off layer in a stripe shape by etching which forms a stripe-like etching mask on a back surface side of the lift-off layer;
stacking a second semiconductor layer on a back surface of a layered body of a semiconductor substrate, the first semiconductor layer and the lift-off layer;
removing a central part of the lift-off layer and the second semiconductor layer stacked thereon, in a condition such that leaves a width-direction end of the lift-off layer in a band shape or line shape; and
stacking a first electrode on a back surface of the first semiconductor layer and
stacking a second electrode on a back surface of the second semiconductor layer.
